(19) United States
(12) Patent Application Publication
(10) Pub. No.: US 2010/0328061 A1
(43) Pub. Date: Dec. 30, 2010

(54) CRIMES AND DISASTERS PREVENTING SYSTEM

(76) Inventor: Rae-Woong Park, Seoul (KR)

Correspondence Address: MATHEWS, SHEPHERD, MCKAY, & BRUNEAU, P.A., 29 THANET ROAD, SUITE 201, PRINCETON, NJ, 08540, US

(21) Appl. No.: 12/811,223

(22) PCT Filed: Nov. 10, 2008
(86) PCT No.: PCT/KR2008/006610

§ 371 Date: Sep. 15, 2010

(30) Foreign Application Priority Data
Jan. 4, 2008 (KR) 1020080001328
May 23, 2008 (KR) 1020080048290

(51) Int. Cl. G08B 1/08; G01R 1/00

(52) U.S. Cl. 340/533; 324/151 R

(57) ABSTRACT

The present invention relates to an emergency signal transmitting and receiving device of a crime and disaster preventing system. The present invention also relates to a device for sensing a state of a cable. The present invention has the advantages that an appropriate action to the emergency state can be achieved. The first embodiment of the present invention can be achieved by a cable sensor, a database and an interpreting device etc. of the emergency state. The second embodiment of the present invention can also be achieved by a simple structure of a permanent magnet, a transformer and an interpreting device etc. of the emergency state.

### TECHNICAL FIELD

The present invention relates to a crime and disaster preventing system and more particularly to an emergency signal transmitting and receiving device of a crime and disaster preventing system.

The present invention also relates to a cable abnormal state sensing device of a crime and disaster preventing system.

### BACKGROUND ART

Recently economic crimes caused by a gap between rich and poor are increasing although there are many rich persons according that economic development is achieved. Therefore, it is very important not only to prevent economic crimes caused by the gap between rich and poor but also to protect various important facilities from the crime and disaster.

To comply with the desires like that there is disclosed a crime and disaster preventing system. Recently there are lots of companies to provide a service for the crime and disaster preventing system to comply with a client's request.

A conventional crime and disaster preventing system has a cable sensor for sensing an abnormal state of the cable and outputting the sensed signal to a processing device. Therefore, the cable sensor is considered as very important component of the crime and disaster preventing system.

However, the cable sensor of the conventional crime and disaster preventing system uses its communicating method with a relay signal, RS485 or RS422 and disposes outside thereby causing a difficulty to transmit the sensed signal to a remote control center because of the falling of a thunderbolt or a noise on the signal line.

Further, there has not been disclosed a device for sensing an abnormal state of the cable as ever.

Therefore, it is impossible to protect various cables thereby causing a difficulty to acknowledge the abnormal state of the cable. Furthermore, it is impossible to sense a leakage of information when the cable for transmitting and receiving various information is used in the system.

Further, because the conventional crime and disaster preventing system uses an optical sensor or a CCD (Charged Couple Device) camera the function for crime and disaster preventing can not be satisfactorily accomplished.

### DISCLOSURE

### Technical Problem

The present invention has been invented to overcome the above problems it is an object of the present invention to provide an emergency signal transmitting and receiving device of a crime and disaster preventing system in which an abnormal state of the cable can be sensed immediately and be taken an appropriate action to the sensed emergency state.

It is another object of the present invention to provide a cable abnormal state sensing device of a crime and disaster preventing system in which an abnormal state of the cable can be sensed immediately and be taken an appropriate action to the sensed emergency state.

### Technical Solution

In order to achieve the above objects, the present invention provides an emergency signal transmitting and receiving device of a crime and disaster preventing system comprising: a cable sensor for sensing an abnormal state, and an emergency signal processing device for receiving and processing the emergency signal from the cable sensor and transmitting the processed emergency signal to remote control center to be taken an appropriate action, wherein said emergency signal processing device includes an emergency signal inputting stage for receiving the emergency signal from the cable sensor; an emergency signal processing stage for processing the emergency signal inputted from the cable sensor by one method of Fast Fourier Transform and Digital Signal Processor; a database for storing the processed emergency signal by the processing stage; and a communicating unit for transmitting the processed emergency signal stored in the database to the remote control center, wherein said emergency signal transmitting method from the cable sensor to the processing unit can be selected one of an optical cable method, capacitance changing method and magnetic force method, wherein said communicating unit can be selected one of RS232, 422, 485S, DTMF (Dual Tone Multi-Frequency), PSK (Phase Shift Keying), ASK (Amplitude Shift Keying), FSK (Frequency Shift keying) and optical communicating method.

In order to achieve the above objects, the present invention provides a cable abnormal state sensing device of a crime and disasters preventing system comprising: a cap including combining pieces having an accommodating space at a predetermined position of junction faces for accommodating permanent magnets, and a long hole to communicate with the accommodating space for being passed the cable; a transformer its first coil connected with the cable to be provided power source; and an analyzing device connected to the second coil of the transformer, wherein said cable comprises an outer cover at its outside, a shield wire disposed inside of the outer cover, and a wire disposed at an internal space of the shield wire, wherein said cap is disposed at a equal distance of the cable therein.

The permanent magnets according to the present invention are their N-poles connected to the cable.

In order to achieve the above objects, the present invention provides a cable abnormal state sensing device of a crime and disaster preventing system comprising: combining pieces for being combined by protrusions and grooves, including an accommodating space at a predetermined position of junction faces for accommodating permanent magnets, and a long hole having an oval shape to communicate with the accommodating space for being passed the cable; two permanent magnets contacted with outside of the cable that shielded tightly by a packing member; and a sensor disposed outside of the cable for sensing electromotive force and noise guided from the magnets to the wire.

### ADVANTAGEOUS EFFECTS

The first embodiment of present invention can provide an emergency signal transmitting and receiving device of a crime and disaster preventing system in which an abnormal state of the cable can be sensed immediately and be taken an appropriate action to the emergency state.

The second and third embodiments of the present invention can provide a cable abnormal state sensing device of a crime and disaster preventing system in which the structure is simple thereby to easy manufacturing of the product to portable and which the cost for establishment and maintenance fees are low.

The second and third embodiments of the present invention can provide a cable abnormal state sensing device of a crime and disaster preventing system in which when the cable is touched by the external factors the flux of the magnets is changed thereby to be induced noise to the wire of the cable so that the sensing device can sense the change of the flux. Therefore, according to the second and third embodiments of the present invention the leakage of information by tapping cable can be prevented. For example, when the cable is touched by the external factors the function of the cable can be stopped so that the leakage of information can be prevented.

The second and third embodiments of the present invention can provide a cable abnormal state sensing device of a crime and disaster preventing system in which the induced voltage is generated to the first coil of the transformer and the changed voltage is induced to the second coil of the transformer when the cable is touched so that the device analyzes the changed waveform induced to the second coil of the transformer and generates light or alarm if the abnormal state is occurred to the cable.

### DESCRIPTION OF DRAWINGS

FIG. 1 is a block diagram of an emergency signal transmitting and receiving device of a crime and disaster preventing system according to the first embodiment of the present invention,

FIG. 2 is a view showing an exterior of a cap according to the second embodiment of the present invention,

FIG. 3 is a longitudinal sectional view showing an internal structure of FIG. 2,

FIG. 4 is a cross sectional view showing an internal structure of FIG. 2.

FIG. 5 is an exemplary view showing established state of the cap of FIG. 2, and

FIG. 6 is a view showing a disjointing state of a cable abnormal state sensing device according to the third embodiment of the present invention.

### BEST MODE

A preferred embodiments according to the present invention will now be in detail described with reference to the accompanying drawings.

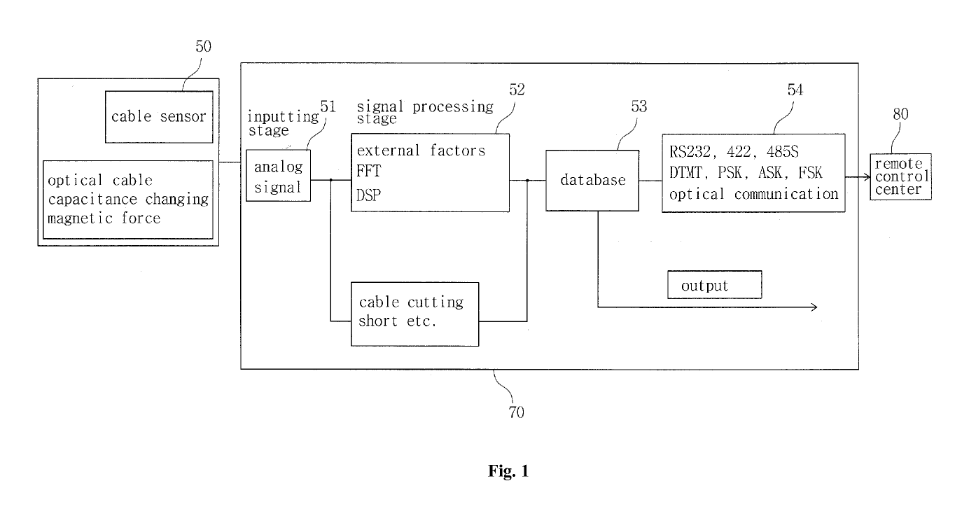

FIG. 1 is a block diagram of an emergency signal transmitting and receiving device of a crime and disaster preventing system according to the first embodiment of the present invention.

As shown in FIG. 1 an emergency signal transmitting and receiving device of a crime and disaster preventing system according to the first embodiment of the present invention comprises a cable sensor 50 for sensing an abnormal state of the cable, and an emergency signal processing device 70 for receiving and processing the emergency signal from the cable sensor 50 and transmitting the processed signal to a remote control center 80 to be taken an appropriate action to the emergency state.

The emergency signal processing device 70 comprises an emergency signal inputting stage 51 for receiving the emergency signal from the cable sensor 50, an emergency signal processing stage 52 for processing the emergency signal inputted from the cable sensor 50 by one method of Fast Fourier Transform and Digital Signal Processor, a database 53 for storing the processed emergency signal by the processing stage 52, and a communicating unit 54 for transmitting the processed signal stored in the database 53 to the remote control center 80.

The emergency signal as an analog signal sensed by the cable sensor 50 is transmitted to the signal inputting stage 51 of the processing device 70 by one method of an optical cable method, a capacitance changing method and a magnetic force method.

The FFT as a processing method at the emergency signal processing stage 52 is that a necessary signal is selected and minimized and is processed by a fast fourier transform, not are transformed of all sampled signal, and DSP is an integrated circuit to rapidly process a digital signal and is sometime used to audio coding to convert an analog audio signal to a digital signal and has a circuit to rapidly process add, subtraction, multiple and divide to rapid process a digital signal.

The communicating unit 54 can use one method of RS232, 422, 485S, DTMT (Dual Tone Multi-Frequency), PSK (Phase Shift Keying), ASK (Amplitude Shift Keying), FSK (Frequency Shift keying) and optical communicating method.

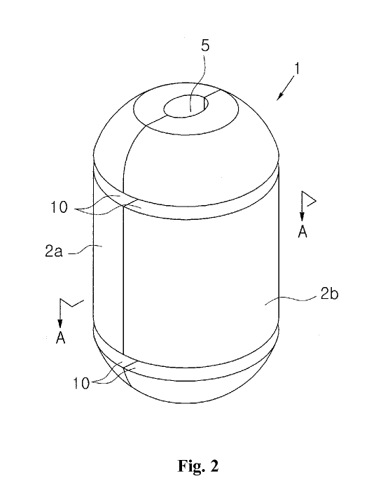

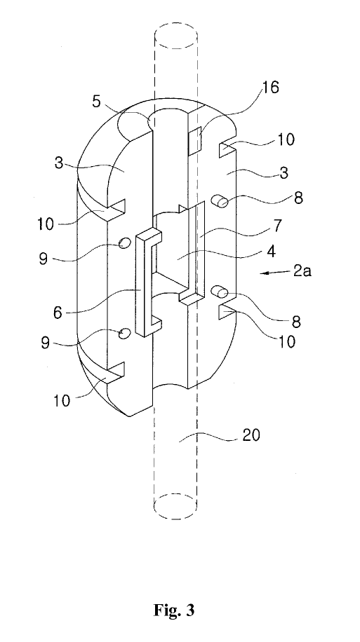

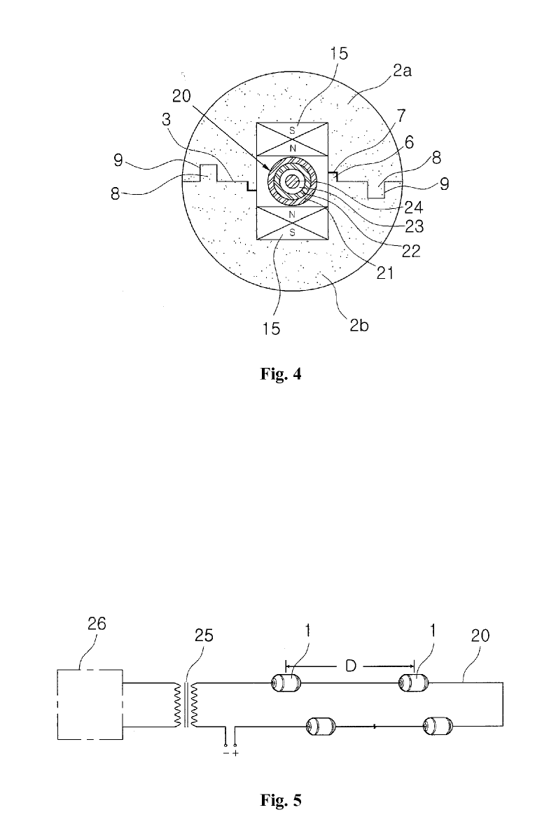

FIGS. 2 to 4 are drawings according to the second embodiment of the present invention. FIG. 2 is a view showing a cap 1 for sensing the abnormal state of the cable, FIG. 3 is a view showing an internal part of combining pieces 2 (2a and 2b) of the cap 1 and FIG. 4 is a longitudinal view showing that the cap 1 is constituted by the combination of a pair of the combining pieces 2.

As shown in FIG. 3 the combining pieces 2 comprises a accommodating space 4 at a predetermined position of junction faces 3 for accommodating permanent magnets, and a long hole 5 to communicate with the accommodating space 4 for being passed the cable 20.

The accommodating space 4 is formed its sides with a long protrusion 6 and a long groove 7 for being inserted the long protrusion 6 thereto and formed their sides with a protrusion 8 and a groove 9 for being inserted the protrusion 8 thereto, respectively when the combining pieces 2a and 2b are combined. The combining pieces 2a and 2b are transversally formed their predetermined position of upper and lower outsides with clip grooves 10.

As the foregoing descriptions the cap 1 according to the present invention is made by combining the combining pieces 2a and 2b accommodating their insides with the cable 20 passing through the long groove 5.

The cable 20 as shown in FIG. 4 comprises an outer cover 21 at its outside, a shield wire 22 disposed inside of the outer cover 21, and a wire 24 disposed at an internal space 23 of the shield wire 22.

Furthermore, as shown in FIG. 4 when the faces 3 of the combining pieces 2 are tightly contacted each other under a state that the cable 20 passes through the long groove 5 thereof the protrusion 6 and the groove 7 are combined and the protrusion 8 and the groove 9 are combined so that the combining pieces 2a and 2b are combined. At this time, N-poles of the permanent magnets 15 accommodated in the space 4 is kept to contact to the outer cover 21 of the cable 20.

As shown in FIG. 5 a transformer 25 is its first coil connected with the cable 20 to be provided power source. There are disposed at a equal distance of the cable 20 on the cap 1. The transformer 25 is its second coil connected with an analyzing device 26.

The analyzing device 26 is a conventional frequency and noise generating sensing device and is preferably connected with an emergency signal generating device not shown for generating light and alarm so that the emergency state is acknowledged.

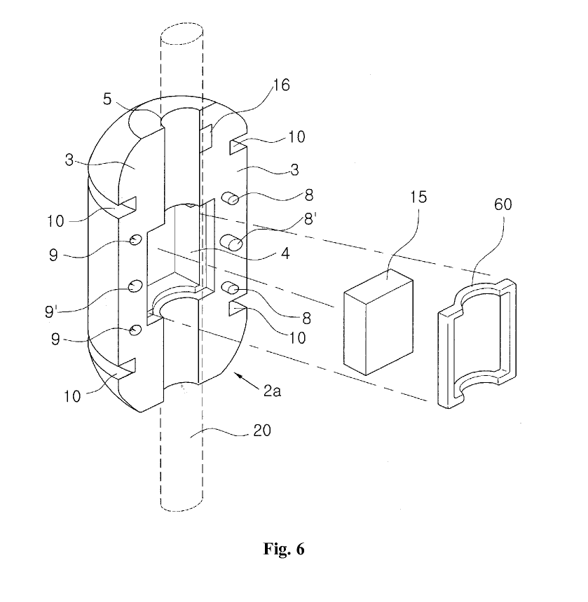

FIG. 6 is a view showing a disjointing state of a device for detecting abnormal state of cable according to the third embodiment of the present invention.

As shown in FIG. 6 the combining pieces 2 comprises an accommodating space 4 at a predetermined position of junction faces 3 for accommodating permanent magnets, and a long hole 5 having an oval shape to communicate with the accommodating space 4 for being passed the cable 20.

The accommodating space 4 is formed its sides with protrusions 8 and 8′ and grooves 9 and 9′ for being inserted the protrusions 8 and 8′ respectively when the combining pieces 2a and 2b are combined. The combining pieces 2a and 2b are transversally formed their predetermined position of upper and lower outsides with clip grooves 10.

The cable 20 is its outside contacted with two permanent magnets 15 that shielded tightly by a packing member 60. The cable 20 is its outside disposed with a sensor 16 for sensing electromotive force and noise guided from the magnets 15 to the wire 24.

### MODE FOR INVENTION

Now, an operation according to the first embodiment of the present invention will be in detail described with reference to the drawings.

When the cable sensor 50 senses an abnormal state of the system according to the present invention by using one method of the optical cable method, the capacitance changing method and the magnetic force method, the sensed signal as analog signal is transmitted to the processing device 70 through the inputting stage 51.

Therefore, the sensed signal inputted to the processing device 70 is converted to the digital signal at the processing stage 52 by one method of FFT and DSP and stored at DB 53 as the emergency signal.

The emergency signal stored DB 53 is transmitted to the remote control center 80 through the communicating unit 54.

Meanwhile, the processing stage 52 processes to determine whether the abnormal state belongs circumstances, such as fence cutting, cable cutting, wire short or climbing over the wall on the basis of the emergency signal sensed by the cable sensor 50.

Next, an operation according to the second and third embodiments of the present invention will be in detail described with reference to the drawings.

The combining pieces 2 of the cap 1 is kept their combined state by being inserted the protrusion 6 to the groove 7 and by being inserted a clip not shown to the clip groove 10.

As shown in FIGS. 3 and 4 when power source is supplied to the device according to the present invention the power source is induced to the second coil via the first coil of the transformer 25. Therefore, the magnets 15 generate the magnetic field, and accordingly the wire 24 generates the magnetic field because of its current so that the device 26 is kept to sense the sine wave under a normal state of the cable 20.

Under the normal state of this when the cable 20 is touched by external factors, for example, an external intruder or a strong wind and so on the cap 1 near the touched point shakes thereby to be changed the position thereof.

As the cable 20 and the cap 1 are changed their positions from the original position, the magnetic field generated by the magnets 15 is instantaneously changed. Therefore, the changed magnetic field of the magnets 15 is generated to the wire 24 of the cable 20 so that the waveform of the sine wave is changed to the distorted waveform included noise thereby to be induced the electromotive force (voltage).

Therefore, the induced voltage is generated to the first coil of the transformer 25 and the changed voltage is induced to the second coil of the transformer 25 so that the device 26 analyzes the changed waveform induced to the second coil of the transformer 25 and generates light or alarm if the abnormal state is occurred to the cable 20.

### INDUSTRIAL APPLICABILITY

The first embodiment of present invention can apply to an emergency signal transmitting and receiving device of a crime and disaster preventing system in which an abnormal state of the cable can be sensed immediately and be taken an appropriate action to the emergency state.

The second and third embodiments of the present invention can apply to a cable abnormal state sensing device of a crime and disaster preventing system in which an abnormal state of the cable can be sensed immediately when the cable is touched by the external factors and be taken an appropriate action to the emergency state and can apply to a communication cable, an audio cable, a precise measuring instrument and a device for sensing coming and going of vehicles.

1. An emergency signal transmitting and receiving device of a crime and disaster preventing system comprising: a cable sensor for sensing an abnormal state; and an emergency signal processing device for receiving and processing the emergency signal from the cable sensor and transmitting the processed emergency signal to remote control center to be taken an appropriate action,
wherein said emergency signal processing device including:
an emergency signal inputting stage for receiving the emergency signal from the cable sensor;
an emergency signal processing stage for processing the emergency signal inputted from the cable sensor by one method of Fast Fourier Transform and Digital Signal Processor;
a database for storing the processed emergency signal by the processing stage; and
a communicating unit for transmitting the processed signal stored in the database to the remote control center
wherein said emergency signal transmitting method from the cable sensor to the processing unit can be selected one of an optical cable method, capacitance changing method and magnetic force method,
wherein said communicating unit can be selected one of RS232, 422, 485S, DTMF (Dual Tone Multi-Frequency), PSK (Phase Shift Keying), ASK (Amplitude Shift Keying), FSK (Frequency Shift keying) and optical communicating method.

2. A cable abnormal state sensing device of a crime and disaster preventing system comprising:
a cap including:
combining pieces having an accommodating space at a predetermined position of junction faces for accommodating permanent magnets, and a long hole to communicate with the accommodating space for being passed a cable;
a transformer its first coil connected with the cable to be provided power source; and
an analyzing device connected to the second coil of the transformer,
wherein said cable comprises an outer cover at its outside, a shield wire disposed inside of the outer cover, and a wire disposed at an internal space of the shield wire,
wherein said cap are disposed at a equal distance of the cable thereon.

3. The cable abnormal state sensing device according to claim 2, wherein said permanent magnets are their N-poles connected to the cable.

4. A cable abnormal state sensing device of a crime and disaster preventing system comprising:
combining pieces for being combined by protrusions 8 and 8′ and grooves 9 and 9′, including: an accommodating space at a predetermined position of junction faces for accommodating a permanent magnet; and a long hole having an oval shape to communicate with the accommodating space for being passed a cable;
two permanent magnets contacted with outside of the cable that shielded tightly by a packing member; and
a sensor disposed outside of the cable for sensing electromotive force and noise guided from the magnets to the wire.
